(19) United States
(12) Patent Application Publication
(10) Pub. No.: US 2022/0415763 A1
(43) Pub. Date: Dec. 29, 2022

(54) Lead Frame Based Molded Radio Frequency Package

(71) Applicant: Ampleon Netherlands B.V., Nijmegen (NL)

(72) Inventors: Jurgen Raben, Nijmegen (NL); Yi Zhu, Nijmegen (NL)

(21) Appl. No.: 17/780,939

(22) PCT Filed: Nov. 29, 2019
(86) PCT No.: PCT/NL2019/050794

§ 371 Date: May 27, 2022

(51) Int. Cl. H01L 23/495; H01L 25/16; H01L 23/31; H03F 1/02

(52) U.S. Cl. CPC H01L 23/49541; H01L 25/16; H01L 23/49575; H01L 23/49562; H01L 23/3121; H03F 1/0288; H01L 23/49589; H01L 24/48

(57) ABSTRACT

Example embodiments relate to lead frame based molded radio frequency packages. One example package includes a substrate. The package also includes a first electrical component arranged on the substrate. Additionally, the package includes a second electrical component. Further, the package includes a plurality of leads that are arranged spaced apart from the substrate and fixed in position relative thereto by a solidified molding compound. The leads were part of a lead frame prior to separating the package from the lead frame. The substrate was physically and electrically connected to the lead frame using a plurality of spaced apart connecting members prior to separating the package from the lead frame. During the separating of the package from the lead frame, each connecting member was divided into a first connecting member part and a second connecting member part. In addition, the package includes a frame part.

The present invention relates to a lead frame based molded radiofrequency package, and to a Doherty amplifier and electronic device comprising the same.

Lead frame based packages are known in the art. The manufacturing process of these packages starts with providing a lead frame that comprises the leads for a plurality of packages. The leads are at that time still connected to a remainder of the lead frame. Typically, the packages are provided with heat conducting substrates, such as copper blocks, to which semiconductor dies are to be mounted. The lead frame is connected to the heat conducting substrates using connecting members. These connecting members may have a form of a metal tab extending from the remainder of the lead frame to corners of the substrate and are often referred to as tie-bars. There, a connection is made between the connecting members and the substrate, for example by means of a riveted connection, a welded connection, a glued connection or a soldered connection.

Using heat conducting substrates, the active circuitry on the semiconductor dies can be efficiently cooled. Typically, the lead frame is used for simultaneously manufacturing a plurality of packages wherein each package to be manufactured is associated with a respective substrate and a respective set of leads.

The lead frame with the substrates connected thereto is subjected to further processing. The exact sequence of processing steps depends on the type of package to be produced. A first type of packages will hereinafter be referred to as over-molded air cavity packages. In these packages, the lead frame with the substrates will be subjected to a molding step during which, for each package to be produced, a ring of solidified material is formed that provides a fixation of the leads relative to the respective substrate. As a next step, the semiconductor die(s) and optionally other electrical components for each package are mounted on the respective substrate and connection between the circuitry on the semiconductor die(s) and the leads is realized using one or more bondwires. As a final step, a lid is provided for each package to be produced, which lid is connected to the ring of solidified molding material to close off the package. In these packages, a cavity is therefore formed between the lid and the substrate in which the semiconductor die(s) and other optional electrical components are arranged.

It is noted that the steps of mounting the semiconductor die(s) and other electrical components and the step of applying the molding compound can be reversed.

In another type of package, hereinafter referred to as over-molded package, the semiconductor die(s) and other optional electrical components are mounted on the substrate and the connection between these components, die(s), and leads using one or more bondwires is realized before applying the molding material. In these packages, the semiconductor die(s), optional other electrical components, and bondwires are encapsulated or covered substantially fully by the molding material. Moreover, the solidified molding material also forms the outer surface of the package.

For both types of packages, one or more separation steps are performed to separate the individual packages from the processed lead frame. Hereinafter, the one or more separation steps will be jointly referred to as separating the package from the lead frame.

The abovementioned one or more separation steps may include punching, cutting, and/or pushing. After having separated the package from the lead frame, a part of the connecting member remains attached to the substrate. This part will hereafter be referred to as the first connecting member part, whereas the part that is still connected to the remainder of the lead frame will be referred to as the second connecting member part.

A common problem associated with packages of the abovementioned type is the limited amount of space inside the package for mounting components. The semiconductor die(s), or optional other components, are typically mounted on the substrate using a fixation material that is at least partially fluid during the mounting of these components. After mounting, the fixation material will solidify to provide an electrical, thermal, and mechanical connection to the substrate. However, the fixation material may also flow to regions outside of the placement area that was originally intended or desired for the semiconductor die or optional other electrical component(s). Consequently, different electrical components can only be arranged inside a single package if they are sufficiently far removed from each other. Otherwise, the fixation material or components thereof may flow out or bleed into other areas of the substrate. As the fixation material is typically conductive, a risk of electrical shorting components or semiconductor die(s) that are mounted or arranged in these other areas exists.

A first object of the invention is to provide a package in which the abovementioned problem associated with spreading or flowing of fixation material is eliminated or at least alleviated.

Another common problem associated with packages of the abovementioned type is the difficulty in obtaining sufficient electromagnetic shielding between different components that are mounted on the substrate. Package size requirements often dictate that the different components should be arranged as close to each other as possible. Such placement will however worsen the electromagnetic coupling between the components.

EP 2892076A2 discloses a Doherty amplifier having a main amplifier and a peak amplifier in between which an isolation wall is arranged to improve isolation between the main and peak amplifiers. As a first example of the isolation wall, the isolation wall may be an erect structure arranged on the substrate. In a further example, the isolation wall is provided with a base extending perpendicular to a main section of the isolation wall. This base can be fixedly attached to the substrate.

A drawback of this first example is that it requires an additional component in addition to the lead frame for manufacturing the semiconductor package. This additional component adds to the bill of materials and increases the number of handling steps.

In a second example, the isolation wall can be formed as a part of the lead frame. More in particular, the lead frame has a plurality of ground fingers that will be connected to a ground node in the final semiconductor package. The isolation wall is initially formed coplanar with a remainder of the lead frame. Prior to assembly of the semiconductor package, the isolation wall is bent transverse to the plane of the lead frame sheet. Links connecting the isolation wall to the ground fingers connects the isolation wall to ground.

A drawback of this second example is that it requires a complex manufacturing process for bending the isolation walls, in particular when multiple isolation walls need to be bent at the same time. Furthermore, additional ground leads are required for grounding the isolation wall. However, the lead configuration is often not dictated by the manufacturer of the semiconductor package but by the customer that incorporates the package in his or her design. Often dual source strategies are employed which would mean that multiple parties should follow the same lead design. Further to the above, adding ground leads will increase the size of the semiconductor package.

US 2015/0311131A1 discloses a semiconductor device having an isolation structure arranged between a first and second circuit to reduce electromagnetic coupling between these circuits. The device comprises a pair of ground connectors to which the isolation structure is coupled. Also in this embodiment, an additional component in addition to the lead frame for manufacturing the semiconductor package is required, thereby adding to the bill of materials and increasing manufacturing complexity and costs.

A second object of the invention is to provide a package in which the abovementioned problems are eliminated or at least alleviated.

According to a first aspect of the invention, the present invention addresses the first object of the invention by providing a lead frame based molded radiofrequency ‘RF’ package that comprises a substrate, a first electrical component arranged on the substrate, a second electrical component, and a plurality of leads that are arranged spaced apart from the substrate and fixed in position relative thereto by a solidified molding compound. At least some of the leads are preferably configured for inputting and outputting electrical signals to and from the package. Moreover, the leads were part of a lead frame prior to separating the package from the lead frame.

The substrate was physically and electrically connected to the lead frame using a plurality of spaced apart connecting members prior to separating the package from the lead frame. During the separating of the package from the lead frame each connecting member was divided, for example by means of cutting, punching or pushing, into a first connecting member part that remained connected to the substrate and a second connecting member part that remained connected to the lead frame.

The first and second electrical components are preferably each, independently from each other, a component chosen from the group consisting of a surface mounted device ‘SMD’, a dielectric having a passive component realized thereon, and a semiconductor die. Other electrical components having multiple terminals and which perform either an active function, e.g. amplification of a signal, or a passive function, e.g. impedance transformation, are not excluded. In some cases the terminals of such components are referred to as lands. The first and second electrical components could include impedance matching network components, such as capacitors and inductors, integrated, distributed or lumped, or amplifying components, such as single-stage or multi-stage amplifiers, or discrete transistors.

The first electrical component can be attached to the substrate using a fixation material that was in an at least partially liquid or fluid state during the attaching of the first electrical component to the substrate.

According to the invention, the package further comprises a frame part that physically connects to and extends from at least one first connecting member part, wherein the second electrical component is mounted and/or electrically connected to the frame part. Here, mounted to should be construed as the second electrical component being in physical contact with the frame part whereas electrically connected to should be construed as the second electrical component having an electrical connection, e.g. via a bondwire, with the frame part.

The frame part of the invention provides an elevated mounting platform relative to the substrate on which the first electrical component is arranged. Such mounting platform can be used to mount the second electrical component or to connect one or more bondwires. Consequently, the risk of the fixation material or components thereof spreading to the mounting platform of for example the second electrical component and creating undesired electrical connections between one or more terminals of the second electrical component, such as an electrical short between one of the terminals and another terminal or ground, can be prevented.

The at least one first connecting member part may be connected to the substrate using rivets, a welded connection, a glued connection, or a soldered connection. Such connections are typically made before arranging the first electrical component. More in particular, the lead frame, including the substrates and the connections between the substrates and the lead frame, typically forms an intermediate product that may be manufactured by a different company than the company that arranges the electrical components and finalizes the package.

A first connecting member part among the at least one first connecting member part may form a lead among the plurality of leads. It is noted that leads, prior to separating the package from a remainder of the lead frame, are connected to the remainder of the lead frame using connecting tabs. According to the invention, the lead(s) formed by the first connecting member part(s) may be connected to substrate using rivets, a welded connection, a glued connection, or a soldered connection. Furthermore, this lead or these leads may each comprise a downset to accommodate between the different height positions of the substrate and the leads. More in particular, all the leads of the package are typically at substantial the same height position relative to the substrate.

Additionally or alternatively, a first connecting member part among the at least one first connecting member part can be physically connected to the substrate at a corner of the substrate, although other positions are not excluded.

As stated above, connecting members may have a form of a metal tab extending from the remainder of the lead frame to corners or other parts of the substrate and are often referred to as tie-bars. In such case, one of the first connecting member parts may comprise a part of the tie-bar whereas the corresponding second connecting member part comprises another part of the tie-bar. Generally, the first connecting member part(s) will not be accessible from the outside of the package or will not extend from the outside of the package as much as the leads do. Furthermore, the first connecting member part(s), when originating from tie-bars, will generally not be physically and electrically connected on the outside of the package.

According to the present invention, an embodiment is possible wherein the frame part extends between a first connecting member part that is formed as a lead, and a first connecting member part that comprises a part of a tie-bar. Alternatively, the frame part extends between a pair of first connecting member parts that are each formed as a lead, or the frame part extends between a pair of first connecting member parts that each comprise a part of a respective tie-bar. The skilled person will appreciate that other combinations are equally possible within the scope of the invention.

The package may further comprise a space between a bottom surface of the frame part that faces the substrate and a top surface of the substrate that faces the frame part. The space may for example be a result of the bottom surface of the frame part being provided with recesses to thereby create spaces, for example in the form of cavities, in between the substrate and the frame part. Additionally or alternatively, the frame part may have an upper surface to which the second electrical component is mounted and/or electrically connected, wherein the frame part displays a step in a direction away from the substrate to allow the second electrical component to be arranged substantially parallel to the substrate.

The space(s) between the top surface of the substrate and the bottom surface of the frame part may at least be partially filed with the solidified molding compound. This provides an additional anchoring of the frame part relative to the substrate. However, it may equally occur that the fixation material or components thereof has/have at least partially spread into the space(s) between the frame part and the substrate. Even if the frame part is conductive, this need not result in undesired electrical connections. For example, if the second electrical component is a semiconductor die having a conductive substrate that needs to be grounded, it does not matter if the fixation material has spread such that it contacts the frame part. Other electrical terminals of the circuitry on the top of the semiconductor die are far removed from the fixation material or the components thereof due to elevated placement of the second electrical component by the frame part.

The frame part may comprise a plurality of stress relief slots. These slots may be at least partially filled by the solidified molding compound. This provides an additional anchoring of the frame part relative to the substrate.

The solidified molding compound may encapsulate the first and second electrical components and may form a lid or top surface of the package. This type of package corresponds to the over-molded package. Alternatively, the package may comprise a lid that is fixedly connected to the leads and/or to the solidified molding compound that fixedly connects the leads and the substrate, wherein a cavity is formed between the lid and the substrate in which the first and second electrical components are arranged. This type of package corresponds to the over-molded air cavity package. In this case, the solidified molding compound that fixedly connects the leads and the substrate may be ring-shaped.

The molding compound may comprise one or more from the materials chosen from the group consisting of thermo-harder and thermo-set materials. The fixation material may be one or more from the group consisting of solder, glue, and metallic sinter material such as silver sinter material. Other materials for the molding compound or fixation material are not excluded.

The frame part, the first connecting member part, the substrate, and the connection between the first connecting member part and the substrate may be conductive. This allows a grounded connection of one or more terminals of the second electrical component via the frame part as the substrate of the package is typically connected to a ground of the device or system the package is arranged in. Furthermore, the frame part, the first connecting member part it is connected to, and the corresponding second connecting member part may have been integrally connected prior to separating the package. For example, the frame part, the first connecting member part it is connected to, and the corresponding second connecting member part may have constituted a single metal part, such as a metal strip. Additionally or alternatively, the frame part may connect the first connecting member part to another first connecting member part. In this case, the frame part, the first and another first connecting member parts it is connected to, and the corresponding second connecting member parts may have been integrally connected prior to separating the package. In this manner, a dam or bridge is formed between the first connecting member part and the other first connecting member part.

The frame part may connect the first connecting member part to a lead among the plurality of leads. In this manner, the lead can be grounded inside the package without requiring additional internal connection such as bondwires.

The second electrical component may have a first and second terminal of which at least the first terminal is connected to the frame part. Hence, the first terminal can efficiently grounded.

The second electrical component may include a second semiconductor die that comprises a conductive substrate of which a first surface that faces the frame part forms a first terminal. A second terminal of the second semiconductor die is then formed on a second surface of the second semiconductor die opposite to the first surface. Additionally or alternatively, the first electrical component may comprise a first semiconductor die. This first semiconductor die may comprise a conductive substrate of which a first surface that faces the substrate part forms a first terminal. A second terminal of the first semiconductor die is then formed on a second surface of the first semiconductor die opposite to the first surface. One or more bondwires may be provided that extend between a bondpad or bondbar arranged on the second surface of the first semiconductor die and a bondpad or bondbar arranged on the second surface of the second semiconductor die.

The first semiconductor die may comprise an RF power transistor that is arranged on the first semiconductor die. The second semiconductor die may comprise one or more passive components, such as an integrated inductor or integrated capacitor, for example forming part of an impedance matching network for the RF power transistor.

The package may comprise a plurality of said first semiconductor dies, and a plurality of said power transistors arranged on the same or different dies among the plurality of first semiconductor dies. The plurality of RF power transistors may form a main amplifier and at least one peak amplifier of a Doherty amplifier. For example, the package may comprise two first semiconductor dies, each die having a power transistor arranged thereon. One of these transistors then forms a main amplifier and one a peak amplifier. These transistors need not be of equal size to allow an asymmetrical Doherty amplifier to be formed. However, embodiments are also possible in which the main and peak amplifiers are realized on a single first semiconductor die. The skilled person will further readily understand that this concept can be extended to multiple first semiconductor dies and multiple peak amplifiers.

The package may further comprise an auxiliary frame part that is electrically isolated from the substrate and the frame part by the solidified molding compound. The auxiliary frame part may have been connected to the lead frame prior to separating the package from the lead frame, and the second electrical component may be mounted on one side to the frame part and on another side to the auxiliary frame part. In this manner, a further mounting platform is realized for the second electrical component separate from the substrate. The auxiliary frame part may be conductive, and the second terminal of the second electrical component may be connected to the auxiliary frame part. Furthermore, the substrate may comprise a recess in which the auxiliary frame part is arranged. This recess is typically filled with solidified molding compound.

The auxiliary frame part may comprise a first frame part member and a second frame part member spaced apart from the first frame part member, wherein the first and second frame part members are electrically connected using a fourth electrical component such as a surface mounted device or a semiconductor die. Similarly, the conductive frame part may comprise a first frame part member and a second frame part member spaced apart from the first frame part member, wherein the first and second frame part members are electrically connected using a third electrical component such as a surface mounted device or a semiconductor die. In these embodiments, the conductive frame part and/or auxiliary frame part is/are not a continuous structure but display(s) a gap between the first and second frame part members. The third/fourth electrical component then spans the gap to electrically connect the first and second frame part members.

According to the first aspect, the present invention also provides a Doherty amplifier that comprises the package having the main and peak amplifiers as defined above. The Doherty amplifier may further comprise a Doherty splitter for splitting an input signal over an input of the main amplifier and an input of the at least one peak amplifier, and a Doherty combiner for combining signals outputted by the main and the at least one peak amplifiers.

The Doherty combiner may comprise an impedance inverter. The Doherty splitter and Doherty combiner may be configured to allow signals amplified by the main and the at least one peak amplifiers to be added in-phase at a combining node in the Doherty combiner. The second electrical component may form at least part of the Doherty combiner and/or Doherty splitter.

According to the first aspect, the present invention also provides an electronic device comprising the package or Doherty amplifier as defined above. This electronic device may be an RF power amplifier, preferably an RF power amplifier for a base station for mobile communications, or an RF power amplifier for a solid state cooking apparatus.

According to a second aspect of the invention, the present invention addresses the second object of the invention by providing a lead frame based molded radiofrequency ‘RF’ package, comprising a substrate, a first electrical component arranged on the substrate, a second electrical component arranged on the substrate, and a plurality of leads that are arranged spaced apart from the substrate and fixed in position relative thereto by a solidified molding compound. At least some of the leads are preferably configured for inputting and outputting electrical signals to and from the package, and they were part of a lead frame prior to separating the package from the lead frame.

The substrate was physically and electrically connected to the lead frame using a plurality of spaced apart connecting members prior to separating the package from the lead frame. Moreover, during the separating of the package from the lead frame, each connecting member was divided, for example by means of cutting, punching or pushing, into a first connecting member part that remained connected to the substrate and a second connecting member part that remained connected to the lead frame.

The first and second electrical components are preferably each, independently from each other, a component chosen from the group consisting of a surface mounted device ‘SMD’, a dielectric having a passive component realized thereon, and a semiconductor die. In addition, the first connecting member part, the substrate, and the connection between the first connecting member part and the substrate are conductive.

According to the second aspect of the invention, the package is characterized in that it further comprises a conductive frame part that physically and electrically connects at least one first connecting member part to another first connecting member part, wherein the first and second electrical components are arranged on opposing sides of the conductive frame part. The conductive frame part provides a conductive barrier that provides electromagnetic shielding between the first and second electrical components.

The Applicant has realized that the first connecting member parts, which generally have no electrical function, can serve as suitable mounting platforms for mounting the conductive frame part. A further advantage is that the first connecting member parts provide a convenient and low inductance path to ground within the package.

The conductive frame part, the at least one first connecting member part and the corresponding second connecting member part(s), the another first connecting member part and the corresponding second connecting member part were preferably integrally connected prior to separating the package. In this manner, the number of components needed for manufacturing the package does not increase. Furthermore, no additional manufacturing steps are required that are specific to the shielding and that cannot be combined with other steps that are required for manufacturing the package.

At least one first connecting member part among the at least one first connecting member part may form a lead among the plurality of leads and/or the another first connecting member part may form a lead among the plurality of leads. Additionally or alternatively, a first connecting member part among the at least one first connecting member part can be physically connected to the substrate at a corner of the substrate, although other positions on the substrate are not excluded.

The conductive frame part may comprise a central part extending from the at least one first connecting member part to the another first connecting member part. The conductive frame part may further comprise one or more side parts connected to a respective side of the central part, wherein the one or mode side parts are bent relative to the central part to provide a conductive wall between the first and second electrical components that preferably extends substantially perpendicular to the substrate.

The first connecting member parts can be connected to the substrate using rivets, a welded connection, a glued connection, or a soldered connection.

The package may further comprise a space between a bottom surface of the conductive frame part that faces the substrate and a top surface of the substrate that faces the conductive frame part. For example, the bottom surface of the conductive frame part may be provided with recesses to thereby create spaces, e.g. in the form of cavities, in between the substrate and the conductive frame part. These spaces may or may not provide a passage underneath the conductive frame part. Moreover, the space(s) between the top surface of the substrate and the bottom surface of the conductive frame part may be at least partially filled with solidified molding compound. This will provide an improved anchoring of the conductive frame part relative to the substrate.

The first and/or second electrical components may be attached to the substrate using a fixation material that was in an at least partially liquid state during the attaching of first and/or second electrical component to the substrate, wherein the fixation material or components thereof has/have at least partially spread into the space(s) between the conductive frame part and the substrate. For example, the fixation material is one or more from the group consisting of solder, glue, and metallic sinter material such as silver sinter material. It should be noted that the conductive frame part may provide a barrier to the fixation material such that the spreading of the fixation material or components thereof used for attaching the first electrical component will not extend to the second electrical component and vice versa.

The frame part may comprise a plurality of stress relief slots. These slots allow for local deformation of the conductive frame part to absorb any mechanical stress in the conductive frame part. These slots may be at least partially filled by the solidified molding compound.

The solidified molding compound may encapsulate the first and second electrical components and may form a lid or top surface of the package. Such package is referred to as an over-molded package. Alternatively, the package may comprise a lid that is fixedly connected to the leads and/or to the solidified molding compound that fixedly connects the leads and the substrate, wherein a cavity is formed between the lid and the substrate in which the first and second electrical components are arranged. Such package is referred to as an over-molded air cavity package. In this latter case, the solidified molding compound that fixedly connects the leads and the substrate may be ring-shaped.

The molding compound may comprise one or more from the materials chosen from the group consisting of thermo-harder and thermo-set materials. Additionally or alternatively, the package may further comprise one or more bondwires extending over the conductive frame part for making an electrical connection between the first and second electrical components. In this case, the conductive frame part may have a locally increased thickness to minimize a gap in between the one or more bondwires and the conductive frame part. In this embodiment, electrical connection between the first and second electrical component can be realized. Such connection does not prevent that parts of the first and second electrical component are shielded from each other. For example, the first and second electrical component may each comprise an integrated circuit, for example in the form of a semiconductor die having electrical circuitry arranged thereon. Sensitive parts of this circuitry on both electrical components may be shielded by the conductive frame part whereas other less sensitive parts of the circuitry on both electrical components may be connected to each other.

The conductive frame part may comprise a first frame part member and a second frame part member spaced apart from the first frame part member, wherein the first and second frame part members are electrically connected using a third electrical component such as a surface mounted device or a semiconductor die. Hence, in this embodiment, the conductive frame part does not comprise a single integral metal structure that spans the distance between the first connecting member parts it is connected to. Instead, a gap is intentionally created by dividing the conductive frame part in at least two frame part members. This gap can be spanned by the third electrical component to allow electrical connection between the first connecting member parts to which the conductive frame part is connected.

In the above, a first aspect and a second aspect of the invention were described. According to the first aspect, the package comprises a frame part that physically connects to and extends from at least one first connecting member part, wherein the second electrical component is mounted and/or electrically connected to the frame part. According to the second aspect, the package comprises a conductive frame part that physically and electrically connects at least one first connecting member part to another first connecting member part, wherein the first and second electrical components are arranged on opposing sides of the conductive frame part. It should be appreciated that both aspects of the invention may be combined. Put differently, the various embodiments presented above concerning the different embodiments may be combined to arrive at a new embodiment. The same holds for the dependent claims describing each aspect of the invention. For example, a dependent claim describing features corresponding to the first aspect may be combined with a dependent claim describing features corresponding to the second aspect.

For example, the conductive frame part of the second aspect may comprise a first frame part member and a second frame part member that are electrically connected using a first electrical component such as a surface mounted device or a semiconductor die. Additionally or alternatively, the package according to the second aspect may comprise a second electrical component such as a semiconductor die or surface mounted device having a first terminal and a second terminal, wherein the second electrical component is mounted with its first terminal to the conductive frame part, the first frame part member or the second frame part member.

Next, the present invention will be described by referring to the appended drawings, wherein:

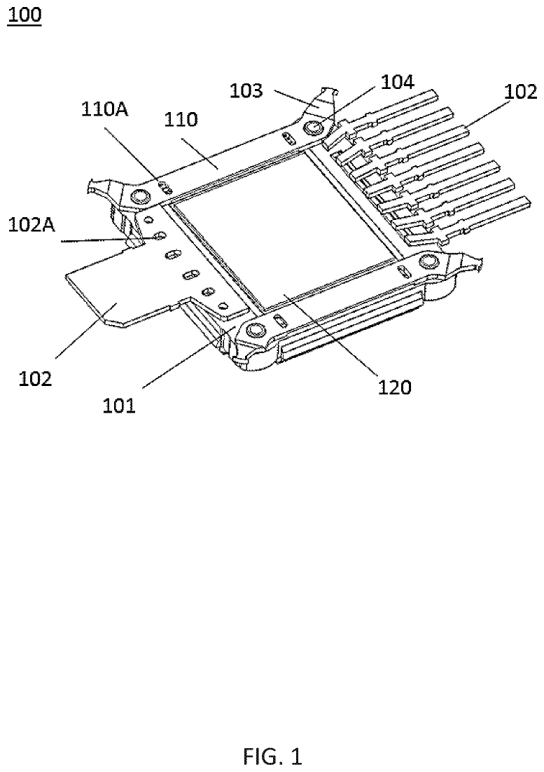

FIG. 1 illustrates a partial view of a first embodiment of a package in accordance with the invention in which a conductive frame part connects two first connecting member parts;

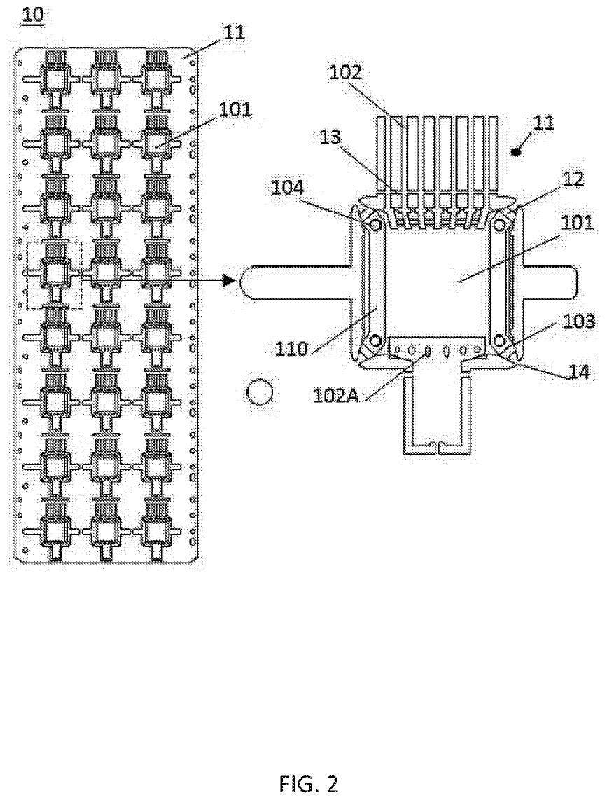

FIG. 2 illustrates an embodiment of a lead frame that was used for the manufacturing of the package of FIG. 1;

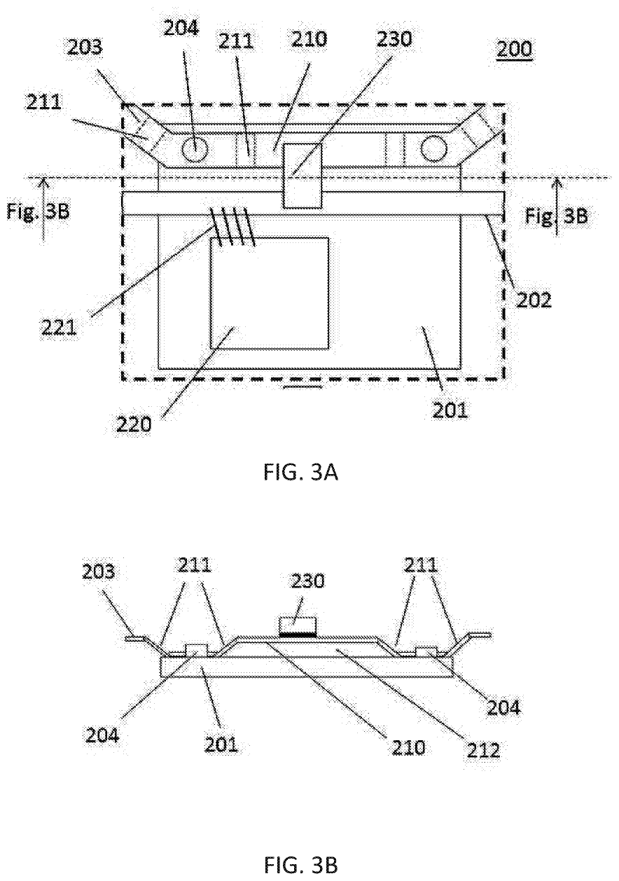

FIGS. 3A and 3B illustrate a schematic top view and side view, respectively, of a second embodiment of a package in accordance with the invention in which the frame part is used for mounting a surface mounted device;

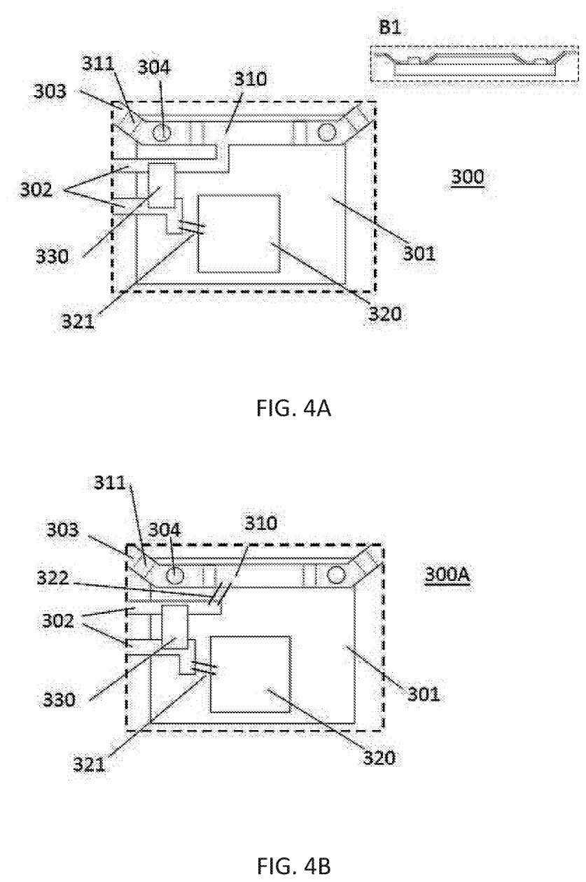

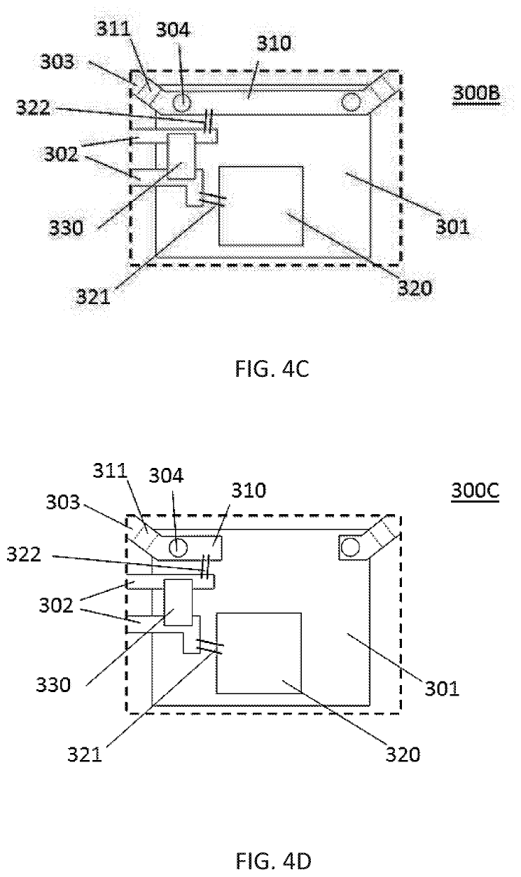

FIGS. 4A-4D illustrates a schematic view of a third embodiment of a package in accordance with the invention in which a conductive frame part is connected to a lead;

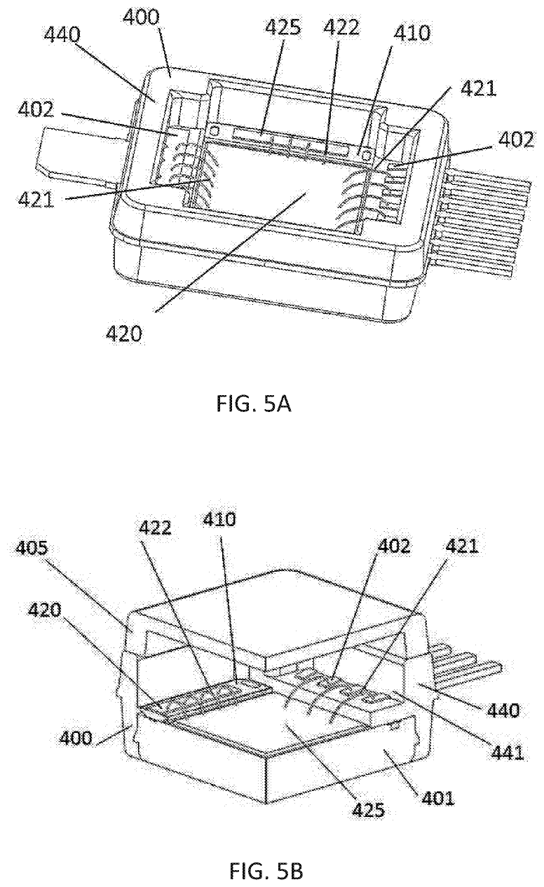

FIG. 5A illustrates a perspective view of an embodiment of an over-molded air cavity package in accordance with the invention without the lid in which a semiconductor die is mounted on the conductive frame part, and wherein FIG. 5B illustrates a corresponding cross sectional view;

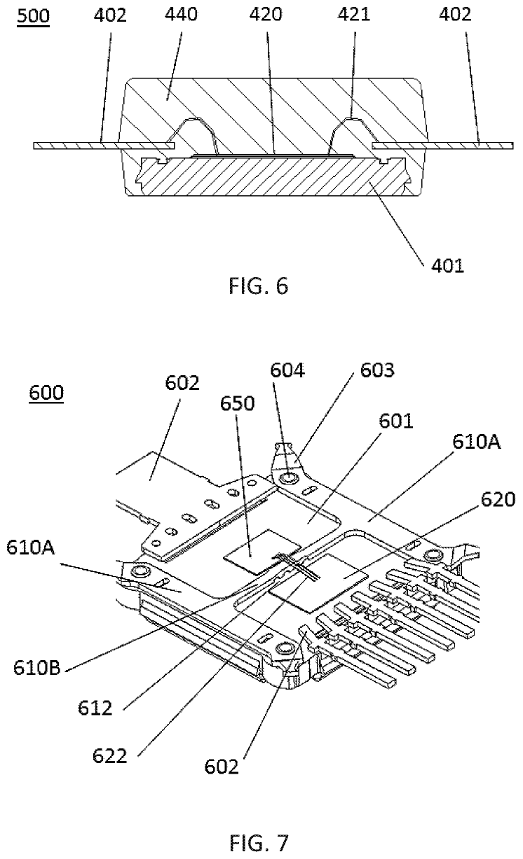

FIG. 6 illustrates a cross sectional view of an embodiment of an over-molded cavity package in accordance with the invention in which a semiconductor die is mounted on the conductive frame part;

FIG. 7 illustrates a sixth embodiment of a package in accordance with the invention in which a conductive frame provides an electromagnetic shield between two electrical components;

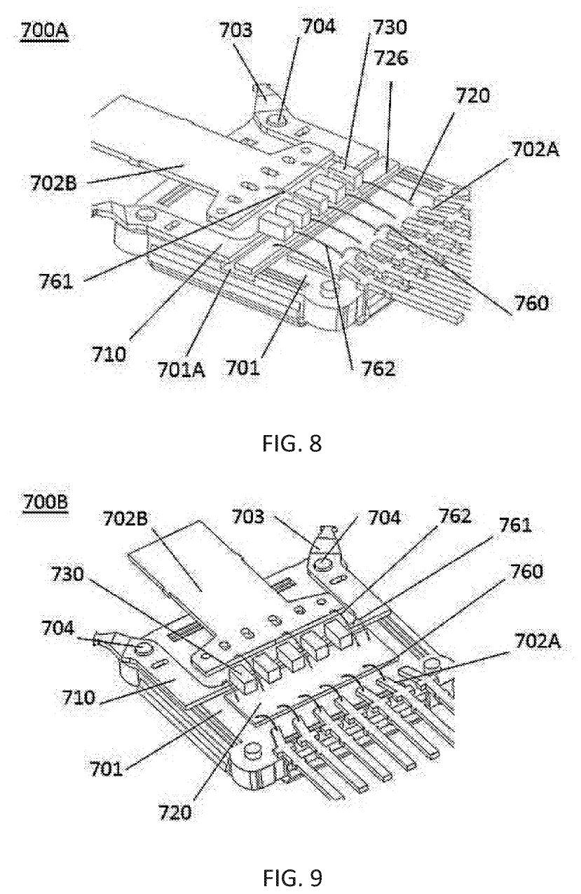

FIGS. 8 and 9 illustrate a seventh and eight embodiment of a package in accordance with the invention in which a conductive frame part provides a mounting surface for mounting a surface mounted device that is connected between the conductive frame part and an auxiliary frame part or a semiconductor die, respectively;

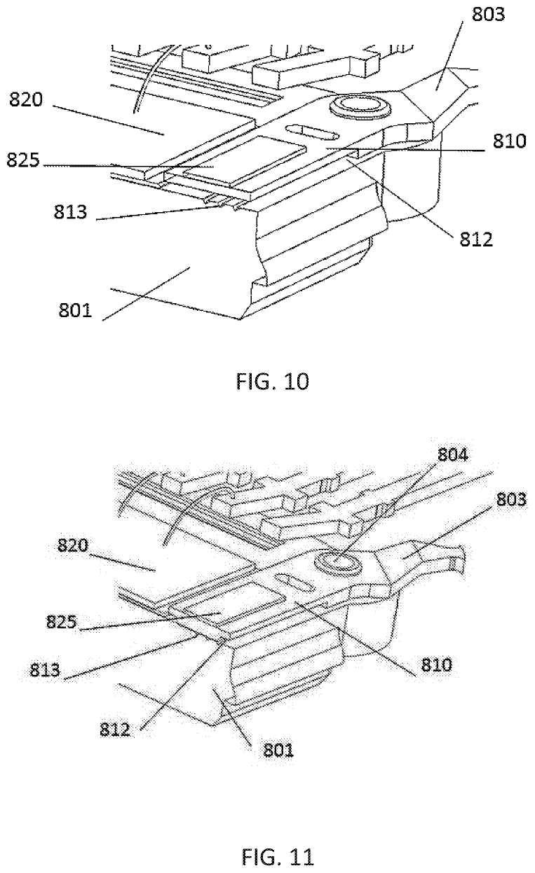

FIGS. 10 and 11 illustrate detailed views of an ninth and tenth embodiment of a package in accordance with the invention in which spaces are provided between a bottom surface of the frame part and a top surface of the substrate;

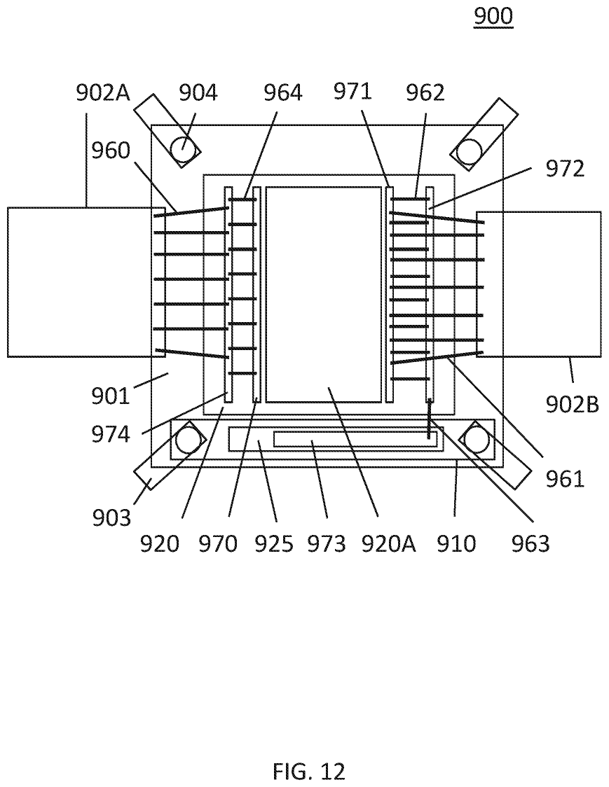

FIG. 12 illustrates a further example of a package in accordance with the invention in which both an active and passive semiconductor die are mounted;

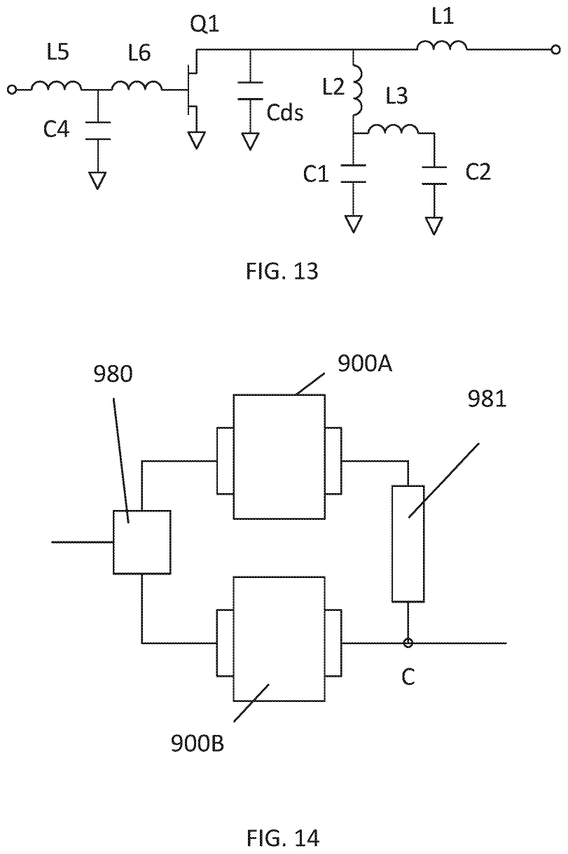

FIG. 13 illustrates an equivalent circuit corresponding to the package of FIG. 12;

FIG. 14 illustrates an example of a Doherty amplifier in accordance with the present invention in which the package of FIG. 12 is used;

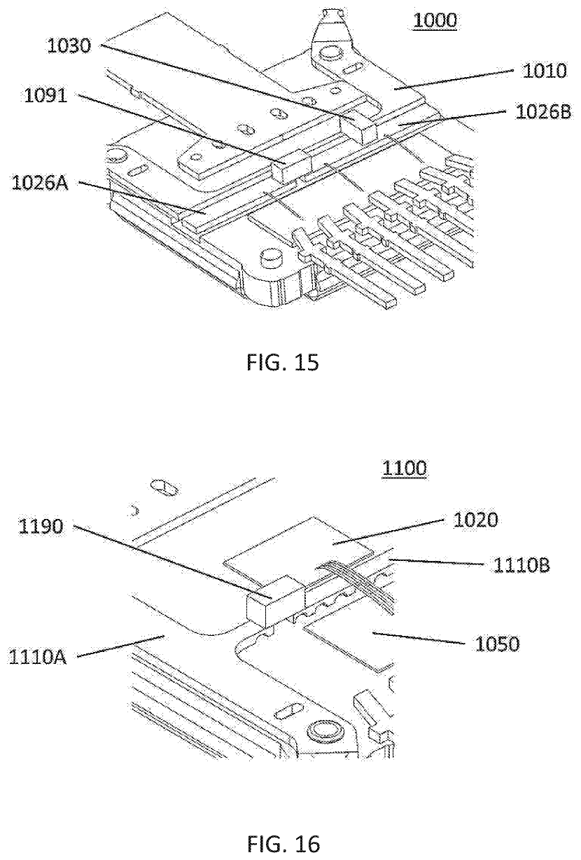

FIGS. 15 and 16 illustrate an eleventh and a twelfth embodiment in which an auxiliary frame part or the frame part is made up of two mutually separated parts, respectively, wherein the parts are connected using an electrical component; and

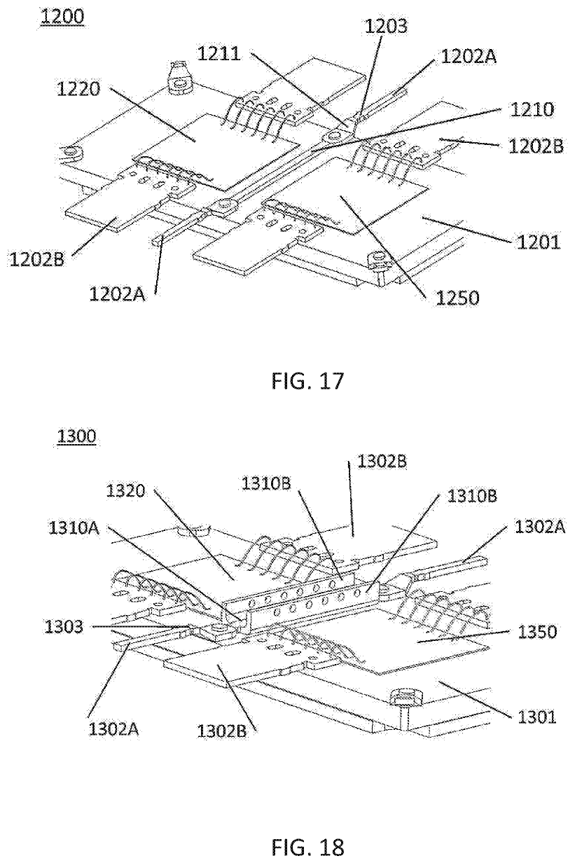

FIGS. 17 and 18 illustrate a thirteenth and fourteenth embodiment, respectively, wherein the frame part is partially formed as leads.

FIG. 1 illustrates a partial view of a first embodiment of a package 100 in which a frame part 110 connects two first connecting member parts 103. First connecting member parts 103 are connected to a substrate 101 using rivets 104.

Package 100 further comprises leads 102 that may be provided with slots 102A. Similarly, slots 110A may be provided in frame part 110 for stress relief purposes. Frame part 110 is preferably conductive.

In the embodiment shown in FIG. 1, a semiconductor die 120 is mounted to substrate 101 using a fixation material that was in an at least partial fluid or liquid state during the attaching of semiconductor die 120. For example, semiconductor die 120 is mounted to substrate 101, for example using a soldering material. Semiconductor die 120 generally has a conductive substrate allowing a convenient ground connection via substrate 101, which is also made of conductive material, such as copper or copper based material.

In FIG. 1, the molding compound is not illustrated. More in particular, FIG. 1 may relate to an over-molded package or to an over-molded air cavity package as described before. For both package types, slots 102A, 110A may be filled with the molding compound thereby improving the fixation of lead 102 and frame part 110, respectively.

FIG. 2 illustrates an embodiment of a lead frame 10 that was used for the manufacturing of package 100. Lead frame 10 comprises a lead frame body 11, a plurality of substrates 101, and a plurality of connecting members 12 by which substrates 101 are connected to lead frame body 11. In addition, a plurality of dam bars 13 is visible by which leads 102 are interconnected.

When separating package 100 from lead frame body 11, dam bars 13 will be severed to mechanically isolate leads 102. In addition, connecting members 12 will be severed thereby creating first connecting member parts 103 that remain attached to a respective substrate 101 and a second connecting member parts 14 that remain connected to lead frame body 11.

As shown in FIG. 2, lead frame body 11, connecting members 12, dam bars 13, leads 102, and frame parts 110 are one integral component prior to separating packages 100 from lead frame body 11. Typically, the integral component comprises a metal strip, for example made from copper, copper-alloy, or other alloy types, that is shaped using techniques such as punching or etching.

FIGS. 3A and 3B illustrate a schematic top view and side view, respectively, of a second embodiment of a package 200 in which a frame part 210 is used for mounting a surface mounted device 230.

Frame part 210, which is conductive, comprises a plurality of downsets 211. Each downset 211 represents a mechanical deformation of frame part 210 to change the positioning thereof relative to substrate 201, see the side view in FIG. 3B. Similar downsets 211 are visible in first connecting member part 203.

As illustrated, a surface mounted device 230 is mounted such that one electrical terminal thereof is connected to frame part 210 and the other terminal thereof to a lead 202. Here, lead 202 extends from one side of package 200 to the opposing side of package 200. Furthermore, in this example, a semiconductor die 220, and more in particular circuitry arranged thereon, is connected to lead 202 using a plurality of bondwires 221.

It should be noted that FIG. 3A, as well as other figures to be discussed next, only illustrates the most relevant components of the invention. Other components, such as bondwires connecting semiconductor die 220 to other leads, are omitted. Nevertheless, as the skilled person will appreciate, such components are not excluded from the invention.

Due to downsets 211, a space 212 exists underneath frame part 210. More in particular, a space 212 exists between an upper surface of substrate 201 and a lower surface of frame part 210.

When semiconductor die 220 is mounted using a fixation material that is in an at least partially liquid state during the attaching of semiconductor die 220, a risk exists that this fixation material, or components thereof, spread(s) out to other areas in the package. As the fixation material is generally conductive, a risk of shorting other components, such as surface mounted devices or other semiconductor dies, may exist. Instead of or in addition to shorting components, other inadvertent electrical connections can result from the fixation material having spread out.

The abovementioned problem is alleviated with the embodiment in FIG. 3A as the surface mounted device is arranged well above substrate 201. Consequently, the risks associated with the spreading out of fixation material are mitigated. In addition, frame part 210, at least the portion between downsets 211 is at substantially the same height as leads 202 allowing other components, such as surface mounted devices 230 to be mounted inside the package.

Depending on the type of package, space 212 may be filled with fixation material or components thereof or solidified molding compound. For example, in over-molded air cavity packages, semiconductor die 220 may be mounted to substrate 201 prior to performing the molding process. In such case, space 212 may be partially filled with fixation material or components thereof and partially filled with solidified molding compound. Alternatively, when the order of molding and die attachment is reversed for over-molded air cavity packages, space 212 may be solely filled with solidified molding compound. For over-molded packages in which no lid is used, all parts and components as seen in FIG. 3 are solely filled and/or covered with molding compound.

FIG. 4A illustrates a schematic view of a third embodiment of a package 300 in which a conductive frame part 310 connects two first connecting member parts 303 and is connected to a lead 302. Optionally, a surface mounted device 330 is arranged between two leads 302 and a semiconductor die 320 may be electrically connected to one or more of leads 302 using one or more bondwires 321.

Using downsets 311, the vertical position of the conductive frame part 310 relative to substrate 301 can be changed from a position in which it lies directly on top of substrate 301, e.g. directly adjacent to rivet 304, to a position in which it lies in plane with leads 302. This is shown in more detail in the small cross sectional view illustrated in dashed box B1.

FIG. 4B illustrates a variant, referred to as package 300A, of the embodiment shown in FIG. 4A wherein bondwires 322 are used for connecting conductive frame part 310 to lead 302. Because there is no integral connection between conductive frame part 310 and lead 302, the deforming impact that a downset 311 may introduce with respect to the mounting of surface mounted device 300 can be avoided. For example, the introduction of downset 311 may result in a non-flat mounting surface for surface mounted device 300. Using bondwires 322, the application of downset 311 is mechanically decoupled from leads 302.

FIG. 4C illustrates a variant, referred to as package 300B, of the embodiment shown in FIG. 4B wherein no downsets 311 are used in between rivets 304. Consequently, conductive frame part 310 is at substantially the same level as substrate 301. In particular, when conductive frame part 310 is connected over its entire length to substrate 301, a low inductance grounding of bondwires 322 can be obtained. Furthermore, the height difference between an upper surface of lead 302 and an upper surface of conductive frame part 310 can easily be overcome by bondwires 322.

It should be noted that in these and other embodiments, conductive frame part 310, having been part of a lead frame is typically at least locally provided with a plating finish, e.g. an Ag spot finish, an Au finish, or a Ni—Pd—Au finish), to render the surface suitable for wire bonding.

FIG. 4D illustrates a variant, referred to as package 300C, of the embodiment shown in FIG. 4C wherein conductive frame part 310 does not extend between two opposing rivets 304.

FIG. 5A illustrates a perspective view of an embodiment of an over-molded air cavity package 400 without the lid in which a semiconductor die 425 is mounted on the conductive frame part 410, and FIG. 5B illustrates a corresponding cross sectional view in which lid 405 is included.

In FIG. 5A, semiconductor die 425 has a conductive substrate. Consequently, circuitry arranged on semiconductor 425 can be easily connected to ground via the conductive substrate, and conductive frame part 410, which part is connected to substrate 401 using conductive rivets. Such connection is particularly useful for low frequency grounding.

FIG. 5A further illustrates a solidified molding compound 440 by which leads 402 and substrate 401 are mutually fixed. Molding compound 440 is ring shaped and leads 402 extend through the body of molding compound 440. An inner end of leads 402 is generally free of molding compound to allow electrical connection to other components using one or more bondwires. In the embodiment shown in FIG. 5A, a semiconductor die 420 is connected to leads 402 using bondwires 421. Similarly, bondwires 422 extend between semiconductor die 420 and semiconductor die 425. For example, semiconductor die 425 may comprise a capacitor of which a first terminal is connected to the conductive substrate of semiconductor die 425 and of which a second terminal is connected, via bondwires 422, to circuitry on semiconductor die 420. For example, semiconductor die 420 may comprise one or more RF power transistors that have their drains connected to the second terminal of the capacitor on semiconductor die 425. Consequently, passive matching circuitry may be arranged on semiconductor die 425 that is accessible for the circuitry on semiconductor die 420.

Similar to FIG. 1, conductive frame part 410 connects two first connecting member parts 403 and is connected to substrate 401 using rivets 404.

The cross sectional view of FIG. 5B illustrates how a lid 405 is fixedly attached, e.g. using glue, to ring shaped solidified molding compound 440. A cavity 441 is thereby formed between lid 440 and substrate 401 in which semiconductor dies 420, 425 are arranged. These packages are therefore referred to as over-molded air cavity packages.

FIG. 6 illustrates a cross sectional view of an embodiment of an over-molded package 500 in which the solidified molding compound 440 also forms the cover of package 500. A separate lid as illustrated in FIG. 5B is therefore not required and an air cavity is not formed inside package 500. It should be noted that in FIG. 6 the same reference signs have been used as in FIG. 5A with the exception that solidified molding compound 440 is not ring shaped but fills the entire package.

FIG. 7 illustrates a sixth embodiment in which a conductive frame part provides an electromagnetic shield between two electrical components 620, 650. Here, the conductive frame part comprises two parallel first sections 610A that each extend between a respective pair of opposing first connecting members parts 603 that are each connected to substrate 601 using rivets 604. First sections 610A are interconnected by a second section 610B. This latter section provides an electromagnetic shielding for components 620, 650. These components may for example be a semiconductor die or any other electrical component that requires shielding.

A connection between components 620, 650 and leads 602 can be obtained using bondwires (not shown). Moreover, bondwires 622 may be used to provide an electrical connection between components 620, 650. Locally, i.e. underneath bondwires 622, second section 610B may have a locally increased thickness to minimize the gap in between bondwires 622 and second section 610B.

Also shown in FIG. 7 are spaces 612 in the form of recesses underneath second section 610B. These recesses, which may or may not provide a passage underneath second section 610B may serve to accumulate fluid or liquid fixation material or components thereof during the attaching of first and/or second component 620, 650, and/or may be filled with solidified molding material as a result of the molding process.

FIGS. 8 and 9 illustrate a seventh embodiment of a package 700A and an eight embodiment of a package 700B in which a conductive frame part 710 provides a mounting surface for mounting a surface mounted device 730 that is connected between conductive frame part 710 and an auxiliary frame part 726 or between conductive frame part 710 a semiconductor die 720, respectively. In both figures, the same reference signs will be used to refer to the same or equivalent components.

Auxiliary frame part 726 is electrically isolated from substrate 701. It may have been connected, preferably integrally, to the lead frame body prior to separating the package from the lead frame. Auxiliary frame part 726 is conductive and it contacts a first terminal of SMD 730 in FIG. 8. Substrate 701 comprises a recess 701A in which auxiliary frame part 726 is arranged. Recess 701A is filled with solidified molding compound thereby fixating auxiliary frame part 726 relative to substrate 701 after separating package 700A from the remainder of the lead frame.

In FIG. 8, the second terminal of SMD 730 is connected to conductive frame part 710. In FIGS. 8 and 9, frame part 710 is U-shaped with the surface mounted device 730 being connected to the base of the U-shape and the legs of the U-shape each being connected to a respective first connecting member part 703, which is connected to substrate 701 using rivets 704.

Packages 700A and 700B further comprise a semiconductor die 720 on which for example an RF power transistor is arranged. An input terminal of semiconductor die 720, e.g. a gate terminal of the power transistor or other electrical circuitry arranged on die 720, is connected to an input lead 702A using one or more input bondwires 760. Instead of a plurality of leads 702A, also one or two leads can be used. Similarly, an output terminal of semiconductor die 720, e.g. a drain terminal of the power transistor, is connected to an output lead 702B using a plurality of bondwires 761. At the same time, the output terminal of semiconductor die 720, or another terminal of semiconductor die 720, is connected to SMD 730. In the embodiment in FIG. 8, this is achieved using matching bondwires 762 that extend from semiconductor die 720 to auxiliary frame part 726.

In the embodiment shown in FIG. 9, SMD's 730 are directly mounted between semiconductor die 720 and conductive frame part 710. In this embodiment, there is no need for an auxiliary frame part 726. Optionally, conductive frame part 710 may be recessed at the position of placement of SMDs 730 such that locally the upper surface of frame part 710 is aligned with the upper surface of semiconductor die 720 to allow a horizontal placement of SMDs 730.

The series combination of SMDs 730 and the inductance associated with bondwires 762 (optional), with SMDs 730, and the connection between the second terminal of SMDs 730 and substrate 701 forms a series L-C network that is configured to act as an inductance at a given frequency in or close to the operational frequency bandwidth. Moreover, the effective inductance of the series L-C network is such that it resonates at the given frequency with the output capacitance of the power transistor arranged on semiconductor die 120. This will mitigate the influence the output capacitance has on RF performance. In this case, SMD 730 may for example be a DC blocking capacitor.

FIGS. 10 and 11 illustrate detailed views of an ninth embodiment of a package 800A and a tenth embodiment of a package 800B in accordance with the invention, respectively, in which spaces 812 are provided between a bottom surface of frame part 810 and the upper surface of substrate 801. FIGS. 10 and 11 further illustrate how a semiconductor die 820 is arranged close to conductive frame part 810 and how a second semiconductor die 825 is arranged on top of conductive frame part 810. As with the other embodiments, a rivet 804 is used to connect conductive frame part 810 and first connecting member part 803 to substrate 801.

FIGS. 10 and 11 also illustrate grooves 813 in substrate 801 that allow an anchoring of substrate 801 during the molding process.

Space 812 underneath conductive frame part 810 may provide a passage, as shown in FIG. 10, or it may have a shape of a recess as shown in FIG. 11. As noted before, space 812 may collect fluid fixation material or components thereof during the attaching of semiconductor die 820 in case the molding process occurs after attaching semiconductor dies 820 to substrate 801, e.g. in the case of over-molded packages. Alternatively, the space may be filled with molding compound if the molding process occurs before attaching semiconductor die, e.g. with over-molded air cavity packages. In both cases, the fixation of conductive frame part 810 is improved.

FIG. 12 illustrates a further example of a package 900 in accordance with the invention in which both an active semiconductor die 920 and a passive semiconductor die 925 are mounted. The equivalent circuit of package 900 is shown in FIG. 13.

On semiconductor die 920, which is mounted on substrate 901, an RF power transistor 920A is arranged which is represented by Q1 in FIG. 13. Furthermore, on semiconductor die 920 an input bondbar 970 is arranged that is connected to the gate of Q1. Similarly, output bondbar 971 is connected to the drain of Q1.

Output bondbar 971 is connected, using matching bondwires 962 to a first auxiliary bondbar 972. This latter bondbar is connected to one terminal of an integrated capacitor on semiconductor die 920, whereas the other terminal of this capacitor is grounded via the conductive substrate of semiconductor die 920.

Output bondbar 971 is also connected to output lead 902B using output bondwires 961. These bondwires are represented by L1 in FIG. 13.

In FIG. 13, the series connection of the integrated capacitor and matching bondwires 962 is represented by C1 and L2, respectively.

As can be seen, first auxiliary bondbar 972 is also connected, using matching bondwires 963, to a second auxiliary bondbar 973 that is arranged on second semiconductor die 925 wherein second semiconductor die 925 is mounted on a conductive frame part 910 that is connected to first connecting member parts 903 and to substrate 901 using rivets 904. On second semiconductor die 925, a high density integrated capacitor is provided, for example a trench capacitor. One terminal of this capacitor is connected to second auxiliary bondbar 973 and the other terminal is grounded via the conductive substrate of second semiconductor die 925 and conductive frame part 910. In FIG. 13, the series connection of the high density capacitor and matching bondwires 963 is represented by C2 and L3, respectively.

At the input side, input bondbar 970 is connected, using matching bondwires 964, to a third auxiliary bondbar 974. This bondbar is connected to one terminal of an integrated capacitor whereas the other terminal of this capacitor is connected to ground via the conductive substrate of semiconductor die 920. Third auxiliary bondbar 974 is also connected, using input bondwires 960 to input lead 902A. Bondwires 960, the integrated capacitor it is connected to, and bondwires 964 are represented by L5, C4, and L6 in FIG. 13, respectively.

Now referring to FIG. 13, a parasitic output capacitance is present at the output of Q1. This capacitance, modeled by Cds, deteriorates the performance of RF power transistor Q1 in the operational frequency bandwidth, which typically lies in a range between 1 and 3 GHz, although other frequency ranges are not excluded.

FIG. 13 illustrates a known solution to overcome this problem. The output network formed by L2, L3, C1, and C2 is configured to resonate with Cds at or close to a given frequency in the operational frequency bandwidth. More in particular, at or close to this frequency, the output network will act as a shunt inductor. This inductor will display a parallel resonance with Cds such that the impact of the latter on the RF performance in the operational frequency bandwidth is mitigated. Typically, the shunt inductor is largely determined by L2.

C2 is much larger than C1, C2 will, at a relatively low frequency, display a parallel resonance with the inductance associated with the biasing network. It should be noted that the invention is not limited to the particular position at which the biasing currents are introduced in the circuit.

The parallel resonance of C2 and inductance associated with the biasing line will introduce a first peak in the effective impedance seen at the drain of the transistor. Another resonance occurs at a higher frequency substantially corresponding to the resonance frequency of C1 and L3. By properly choosing the component values for L2, L3, C1, and C3 a desired impedance behavior can be realized in the frequency range typically associated with second order intermodulation products. In this range, the impedance seen by RF power transistor Q1 should be as low as possible to avoid performance degradation.

FIG. 14 illustrates an example of a Doherty amplifier in accordance with the present invention in which the package of FIG. 12 is used. The Doherty amplifier shown in FIG. 14 comprises a first package 900A, similar to package 900, in which a first RF power transistor is arranged. This RF power transistor acts as the main amplifier of the Doherty amplifier. In a second package 900B, similar to package 900, a second RF power transistor is arranged. This RF power transistor acts as the peak amplifier of the Doherty amplifier.

It should be noted that packages 900A and 900B may comprise a different matching network than the network shown in FIG. 13. However, in such matching network, at least a part of the passive circuitry is realized on second semiconductor die 925.

FIG. 14 further illustrates a Doherty splitter 980 that splits an input signal over the inputs of packages 900A, 900B, while at the same time delaying the signal fed to package 900B by 90 degrees at the frequency of interest.

The Doherty amplifier further comprises a Doherty combiner 981 that is connected in between a combining point C and the output of package 900A. Doherty combiner 981 comprises an impedance inverter. The inclusion of Doherty combiner 981 introduces a phase shift between signals outputted by the package 900A and package 900B. However, this phase shaft is compensated by the phase shift introduced by Doherty splitter 980 such that the signals outputted by packages 900A, 900B combine in-phase at combining point C.

In the example above, the dies on which the main and peak amplifiers were realized were housed in different packages. In an embodiment, these dies can be arranged in a package as described above. For example, these dies could be arranged in a single package wherein at least part of the circuitry required for the Doherty splitter and/or combiner is realized as a second semiconductor die or other component mounted to the conductive frame part. In a further or different embodiment, the abovementioned dies are electromagnetically shielded from each other using a conductive frame part as shown in FIG. 7. Such frame part could divide the substrate in two parts, each representing a respective mounting area for the two active semiconductor dies on which the main and peak amplifier are realized.

FIG. 15 further illustrates a further example of a package 1000 in which an auxiliary frame part is used similar to auxiliary frame part 726 in FIG. 8. However, in FIG. 15 the auxiliary frame part comprises a first frame part member 1026A and a second frame part member 1026B. A gap exists between members 1026A, 1026B. However, members 1026A, 1026B are electrically connected using a fourth electrical component 1091 in the form of a surface mounted device. Similar to FIG. 8, a further electrical component in the form a surface mounted device 1030 is arranged in between conductive frame part 1010 and second frame part member 1026B. As illustrated, first and second frame part members 1026A, 1026B, and conductive frame part 1010 provide convenient mounting platforms for mounting electrical components.

Package 1100 shown in FIG. 16 comprises electrical components 1020, 1050 that are isolated from each other using a conductive frame part similar to that shown in FIG. 7. However in this case, the conductive frame part comprises a first frame part member 1110A and a second frame part member 1110B that are spaced apart from each other. A third electrical component 1190 in the form of a surface mounted device electrically connects frame part members 1110A, 1110B.

Package 1200 shown in FIG. 17 comprises a dual line up comprising two semiconductor dies 1220, 1250 that are mounted to substrate 1201 and are each connected to an input lead and an output lead both of which are referred to as 1202B. Conductive frame part 1210 extends between two opposing first connecting members parts 1203 that are at least partially shaped as a lead 1202A. To this end, a downset 1211 is used to bring first connecting member parts 1203 down to the level of substrate 1201. Alternatively, leads 1202A may be omitted while still having conductive frame part 1210 connected to substrate 1201.

In package 1300 shown in FIG. 18, the conductive frame part comprises a central part 1310A that extends between first connecting member parts 1303. The conductive frame part further comprises side parts 1310B connected on opposite sides of central part 1310A. Side parts 1310B are bent such that these parts extend substantially perpendicular to substrate 1301. In this manner, an improved isolation can be achieved between semiconductor dies 1320, 1350.

In packages 1200 and 1300, input leads 1202B, 1302B corresponding to both semiconductor dies 1320, 1350, are arranged on opposite sides of lead 1202A, 1302A that corresponds to the conductive frame part. A similar configuration of leads is used at the output side. This arrangement of leads further improves the isolation between the leads corresponding to semiconductor dies 1320, 1350.

It should be noted that packages 1200 and 1300 can also be embodied without using a molding compound. However, packages 1200 and 1300 are preferably manufactured using over-molding techniques with or without the formation of air cavities inside the package.

In the description above, the invention has been explained using a detailed description thereof. The skilled person will however understand that the prevent invention is not limited to these embodiments and that various modifications can be made without departing from the scope of the invention which is defined by the appended claims and their equivalents.

### LIST OF REFERENCE SIGNS

Lead frame 10
Lead frame body 11
Connecting member 12
Dam bar 13
Second connecting member part 14
Package 100, 200, 300, 400, 500, 600, 700, 800, 900, 900A, 900B, 1000, 1100, 1200, 1300
Substrate 101, 201, 301, 401, 501, 601, 701, 801, 901, 1201, 1301
Lead 102, 202, 302, 402, 602, 702, 802, 902A, 902B, 1202A, 1202B, 1302A, 1302B
Slot in lead 102A
First connecting member part 103, 203, 303, 403, 603, 703, 803, 903, 1203, 1303
Rivet 104, 204, 304, 404, 604, 704, 804, 904
Frame part 110, 210, 310, 410, 610, 710, 810, 910, 1010
Slot in frame part 110A
Semiconductor die 120, 220, 320, 420, 520, 720, 820, 920
Downset 211, 311
Space underneath frame part 212, 612, 812
Bond wires 221, 321, 322, 421, 422, 621
Bond wires 422
Surface mounted device 230, 330, 730
Lid 405
Second semiconductor die 425, 825
Molding compound 440
Cavity 441
First section frame part 610A
Second section frame part 610B
First electrical component 620, 820, 1020, 1220, 1320
Second electrical component 650, 850, 1050, 1250, 1350
Recess substrate 701A
Input lead 702A, 902A
Output lead 702B, 902B
Auxiliary frame part 726
Input bondwire 760
Output bondwire 761
Matching bondwire 762
Groove substrate 813
Passive semiconductor die 925
Input bondwires 960
Output bondwires 961
Matching bondwires 962, 963, 964
Input bondbar 970
Output bondbar 971
First auxiliary bondbar 972
Second auxiliary bondbar 973
Third auxiliary bondbar 974
Doherty splitter 980
Doherty combiner 981
Combining point
First frame part member 1026A, 1110A
Second frame part member 1026B, 1110B
Surface mounted device 1030
Fourth electrical component 1091
Third electrical component 1190
Central part 1310A
Side part 1310B

1. (canceled)

2. (canceled)

3. (canceled)

4. (canceled)

5. (canceled)

6. (canceled)

7. (canceled)

8. (canceled)

9. (canceled)

10. (canceled)

11. (canceled)

12. (canceled)

13. (canceled)

14. (canceled)

15. (canceled)

16. (canceled)

17. (canceled)

18. (canceled)

19. (canceled)

20. (canceled)

21. (canceled)

22. (canceled)

23. (canceled)

24. (canceled)

25. (canceled)

26. (canceled)

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)

43. (canceled)

44. (canceled)

45. (canceled)

46. (canceled)

47. (canceled)

48. (canceled)

49. (canceled)

50. (canceled)

51. (canceled)

52. (canceled)

53. (canceled)

54. (canceled)

55. (canceled)

56. A lead frame based molded radiofrequency (RF) package, comprising:
a substrate;
a first electrical component arranged on the substrate;
a second electrical component;
a plurality of leads that are arranged spaced apart from the substrate and fixed in position relative thereto by a solidified molding compound, wherein the leads were part of a lead frame prior to separating the package from the lead frame, wherein the substrate was physically and electrically connected to the lead frame using a plurality of spaced apart connecting members prior to separating the package from the lead frame, and wherein, during the separating of the package from the lead frame, each connecting member was divided into a first connecting member part that remained connected to the substrate and a second connecting member part that remained connected to the lead frame; and
a frame part that physically connects to and extends from at least one first connecting member part, wherein the second electrical component is mounted to the frame part, said frame part having a bottom surface facing substrate, and said substrate having a top surface that faces the frame part.

57. The package according to claim 56, wherein the first electrical component is a surface mounted device (SMD), a dielectric having a passive component realized thereon, or a semiconductor die, and wherein the second electrical component is a SMD, a dielectric having a passive component realized thereon, or a semiconductor die.

58. The package according to claim 56, wherein the at least one first connecting member part is connected to the substrate using rivets, a welded connection, a glued connection, or a soldered connection.

59. The package according to claim 56, wherein a first connecting member part among said at least one first connecting member part forms a lead among said plurality of leads.

60. The package according to claim 56, wherein a first connecting member part among said at least one first connecting member part is physically connected to the substrate at a corner of the substrate.

61. The package according to claim 56, further comprising a space between the bottom surface of the frame part and the top surface of the substrate.

62. The package according to claim 61, wherein:
the bottom surface of the frame part is provided with recesses to thereby create spaces in between the substrate and the frame part; or
the frame part has an upper surface to which the second electrical component is mounted, said frame part displaying a step in a direction away from the substrate to allow the further electrical component to be arranged substantially parallel to the substrate; or
the space(s) between the top surface of the substrate and the bottom surface of the frame part are at least partially filled with the solidified molding compound; or
a fixation material or components thereof has/have at least partially spread into the space(s) between the frame part and the substrate.

63. The package according to claim 62, wherein the bottom surface of the frame part is provided with the recesses to thereby create the spaces in between the substrate and the frame part, and wherein the spaces created by the recesses of the bottom surface of the frame part are cavities.

64. The package according to claim 56, wherein the frame part comprises a plurality of stress relief slots, wherein the slots are preferably at least partially filled by the solidified molding compound.

65. The package according to claim 56, wherein:
the solidified molding compound encapsulates the first and second electrical components and forms a lid or top surface of the package; or
the package further comprises a lid that is fixedly connected to the leads and/or to the solidified molding compound that fixedly connects the leads and the substrate, wherein a cavity is formed between the lid and the substrate in which the first and second electrical components are arranged, and wherein the solidified molding compound that fixedly connects the leads and the substrate is ring-shaped.

66. The package according to claim 56, wherein:
the molding compound comprises thermo-harder and thermo-set materials; or
a fixation material comprises solder, glue, metallic sinter material.

67. The package according to claim 66, wherein the fixation material comprises metallic sinter material, and wherein the metallic sinter material comprises silver sinter material.

68. The package according to claim 56, wherein the frame part, the first connecting member part, the substrate, and the connection between the first connecting member part and the substrate are conductive, and
wherein:
the frame part, the first connecting member part to which the frame part is connected, and the corresponding second connecting member part are integrally connected prior to separating the package; or
the frame part connects the first connecting member part to another first connecting member part, wherein the frame part, the first and another first connecting member parts to which the frame part is connected, and the corresponding second connecting member parts were integrally connected prior to separating the package; or
the frame part connects the first connecting member part to a lead among the plurality of leads.

69. The package according claim 68, further comprising an auxiliary frame part that is electrically isolated from the substrate and the frame part by the solidified molding compound, said auxiliary frame part having been connected to the lead frame prior to separating the package from the lead frame,
wherein the second electrical component is mounted on one side to the frame part and on another side to the auxiliary frame part,
wherein the substrate comprises a recess in which the auxiliary frame part is arranged,
wherein the auxiliary frame part comprises a first frame part member and a second frame part member spaced apart from the first frame part member, and
wherein the first and second frame part members are electrically connected using a fourth electrical component such as a surface mounted device or a semiconductor die.

70. The package according to claim 68, wherein the conductive frame part comprises a first frame part member and a second frame part member spaced apart from the first frame part member, and wherein the first and second frame part members are electrically connected using a third electrical component such as a surface mounted device or a semiconductor die.

71. The package according to claim 68, wherein the second electrical component has a first and second terminal of which at least the first terminal is connected to the frame part.

72. The package according to claim 71,
wherein the second electrical component comprises a second semiconductor die,
wherein the second semiconductor die comprises a conductive substrate of which a first surface that faces the frame part forms a first terminal, a second terminal of the second semiconductor die being formed on a second surface of the second semiconductor die opposite to the first surface,
wherein the first electrical component comprises a first semiconductor die,
wherein the first semiconductor die comprises a conductive substrate of which a first surface that faces the substrate forms a first terminal, a second terminal of the first semiconductor die being formed on a second surface of the first semiconductor die opposite to the first surface,
wherein the package further comprises one or more bondwires that extend between a bondpad or bondbar arranged on the second surface of the first semiconductor die and a bondpad or bondbar arranged on the second surface of the second semiconductor die,
wherein the first semiconductor die comprises an RF power transistor that is arranged on the first semiconductor die,
wherein the second semiconductor die comprises one or more passive components,
wherein the package comprises a plurality of said first semiconductor dies and a plurality of said power transistors arranged on the same or different dies among the plurality of first semiconductor dies, and
wherein the plurality of RF power transistors form a main amplifier and at least one peak amplifier of a Doherty amplifier.

73. A Doherty amplifier, comprising the package as defined in claim 72, and further comprising:
a Doherty splitter for splitting an input signal over an input of the main amplifier and an input of the at least one peak amplifier; and
a Doherty combiner for combining signals outputted by the main and the at least one peak amplifiers,
wherein the Doherty combiner comprises an impedance inverter,
wherein the Doherty splitter and Doherty combiner are configured to allow signals amplified by the main and the at least one peak amplifiers to be added in-phase at a combining node in the Doherty combiner, and
wherein the second electrical component forms at least part of the Doherty combiner and/or the Doherty splitter.

74. An electronic device comprising the package as defined claim 56, wherein the electronic device is an RF power amplifier.

75. The electronic device of claim 74, wherein the RF power amplifier is an RF power amplifier for a base station for mobile communications or an RF power amplifier for a solid-state cooking apparatus.
